(19) United States
(12) Patent Application Publication
(10) Pub. No.: US 2013/0091364 A1
(43) Pub. Date: Apr. 11, 2013

(54) RANDOM ACCESS MEMORY MODULE WITH DRIVING VOLTAGE ADAPTOR AND COMPUTING APPARATUS

(71) Applicant: JIE LI, Shenzhen City (CN)

(72) Inventor: JIE LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/332,383

(22) Filed: Dec. 21, 2011

(30) Foreign Application Priority Data
Oct. 6, 2011 (CN) 201110292896.1

(51) Int. Cl. G11C 5/14; G06F 1/26

(52) U.S. Cl. 713/300; 365/226

(57) ABSTRACT

A random access memory (RAM) module includes a power input terminal for receiving a power voltage; memory units for data storage; and a driving voltage adaptor electrically connected between the power input terminal and the memory units. The driving voltage adaptor receives the power voltage from the power input terminal, converts the power voltage into a driving voltage with a predetermined value, and outputs the driving voltage to the memory units.

### BACKGROUND

1. Technical Field

The present disclosure relates to a random access memory (RAM) module and a computing apparatus using the RAM module.

2. Description of Related Art

RAM modules are computer components for temporary data storage. For example, a RAM module is normally plugged in and electrically connected with a memory slot in a motherboard of a computing apparatus, and is supplied with a driving voltage by a power supply module within the computing apparatus.

In practice, different types of DDR3 RAM modules may need different driving voltages. However, all the different RAM modules can be plugged into a same DDR3 memory slot of the motherboard.

When the computing apparatus starts to work, the motherboard is unaware of the type of RAM module plugged in the DDR3 memory slot, and the power supply module may provide a default driving voltage such as 1.5V to the DDR3 memory slot. After a central processing unit (CPU) of the computing apparatus is initiated and detects that the RAM module plugged in the DDR3 memory slot requires a lower driving voltage, the CPU may control the power supply module to change the default driving voltage into another suitable driving voltage such as 1.35V or 1.25V. However, before the driving voltage is changed, the RAM plugged in the DDR3 memory slot needs to endure the excessive driving voltage, this may shorten a life of the RAM module or even destroy the RAM module.

What is needed is to provide a RAM module that can overcome the aforementioned limitations.

### BRIEF DESCRIPTION OF THE DRAWINGS

The components in the drawings are not necessarily drawn to scale, the emphasis instead being placed upon clearly illustrating the principles of at least one embodiment. In the drawings, like reference numerals designate corresponding parts throughout the various views.

FIG. 1 schematically illustrates a block diagram of a RAM module according to an embodiment of the present disclosure.

FIG. 2 schematically illustrates a diagram of a computing apparatus according to another embodiment of the present disclosure.

### DETAILED DESCRIPTION

Reference will now be made to the drawings to describe specific exemplary embodiments of the present disclosure in detail.

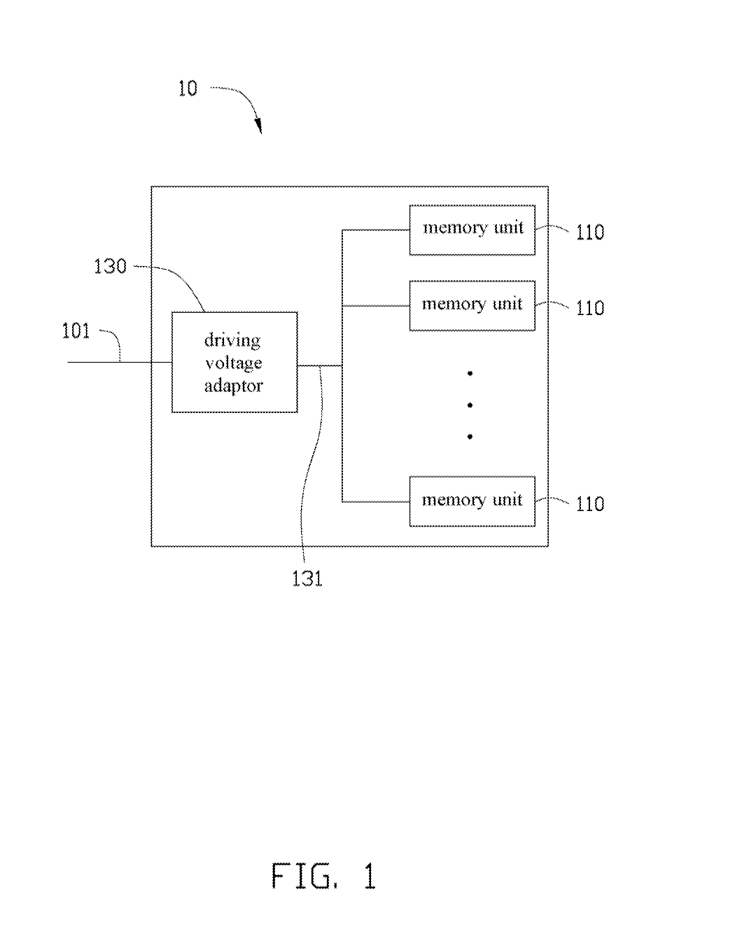

FIG. 1 is a block diagram of a RAM module 10 according to an embodiment of the present disclosure. The RAM module 10 includes a power input terminal 101, a plurality of memory units 110, and a driving voltage adaptor 130.

The power input terminal 101 receives a power voltage from an external power supply module (not shown). The driving voltage adaptor 130 is electrically connected between the power input terminal 101 and the memory units 110, and provides a driving voltage to the memory units 110 via a voltage output terminal 131. The memory units 110 are driven with the driving voltage to implement a data storage function.

The driving voltage adaptor 130 may be a voltage conversion circuit. The driving voltage adaptor 130 receives the power voltage from the power input terminal 101, converts the power voltage into a driving voltage having a predetermined value, and then outputs the driving voltage to the memory units via the voltage output terminal 131. The output driving voltage of the driving voltage adaptor 130 is predetermined according to a type of the memory units 110.

All of the memory units 110 may be a same type of RAM units requiring a same driving voltage. In one embodiment, the memory units 110 may be DDR3 SDRAM units requiring a first driving voltage of 1.5V, or DDR3L SDRAM units requiring a second driving voltage of 1.35V, or DDR3U SDRAM units requiring a third driving voltage of 1.25V. Correspondingly, the driving voltage adaptor 130 may be a buck circuit that converts a power voltage (e.g. 1.5V) received by the power input terminal 101 into a lower driving voltage (e.g. 1.35V or 1.25V). In alternative embodiments, the memory units 110 may also be DDR2 SDRAM units requiring a fourth driving voltage of 1.8V, or DDR SDRAM units requiring a fifth driving voltage of 2.6V, or other types of SDRAM units. Correspondingly, the driving voltage adaptor 130 may be a boost circuit that converts a power voltage (e.g. 1.5V) received by the power input terminal 101 into a greater driving voltage (e.g. 1.8V or 2.6V).

Each of the memory units 110 may take a form of an IC located on a printed circuit board (PCB). Data can be written into or read from the memory units 110 via corresponding pins of the PCB, and the power input terminal 101 may also be configured as one of the pins of the PCB, namely, a power pin. Moreover, the driving voltage adaptor 130 can also be in a form of an IC located on the PCB, for example, the driving voltage adaptor 130 may be a digital direct current to direct current (DC/DC) converter chip of a ZL9101M type. As such, the memory units 110 and the driving voltage adaptor 130 are integrated into a same PCB to form the one-piece RAM module 10.

In the RAM module 10 as illustrated above, the driving voltage adaptor 130 can ensure the memory units 110 are provided with a driving voltage with a suitable value. Therefore, the memory units 110 can be prevented from enduring excessive driving voltage, and consequently the reliability of the RAM module 10 can be improved and a long lifetime of the RAM module 10 can be ensured.

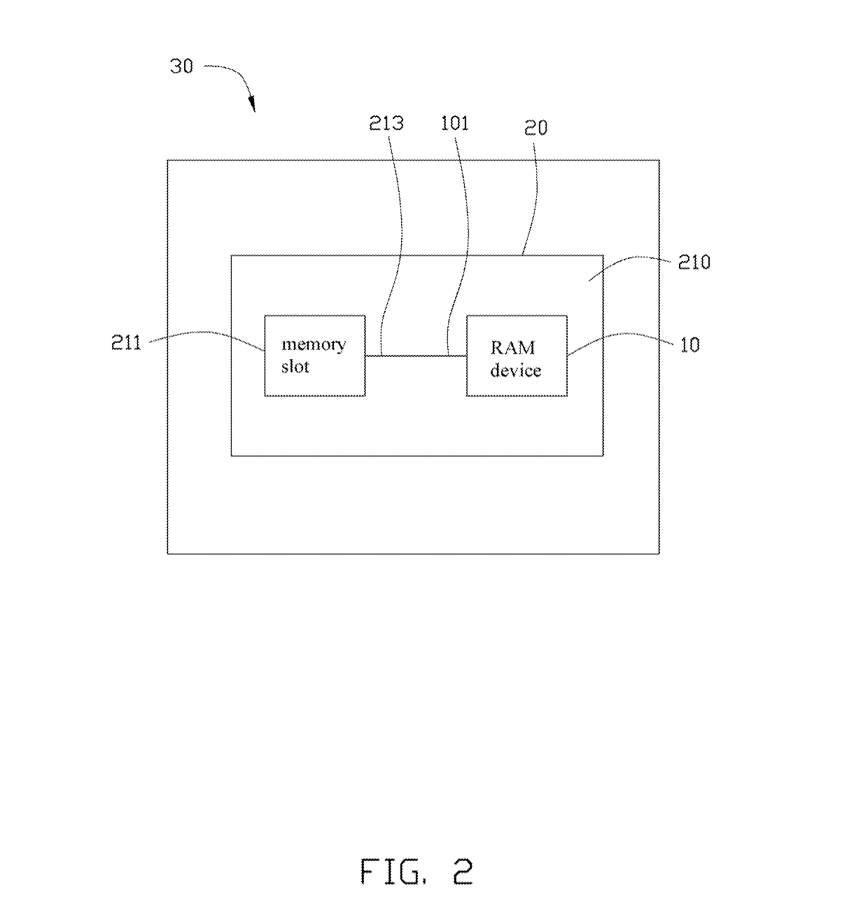

FIG. 2 schematically illustrates a diagram of a computing apparatus 30 according to another embodiment of the present disclosure. The computing apparatus 30 includes a motherboard 20 and a RAM module 10 pluggably installed on the motherboard 20.

The motherboard 20 may include a circuit board 210 including a plurality of function module, such as a CPU. The function modules cooperate to implement various functions of the computing apparatus 30, such as data processing, computer status control and slave apparatus status control. In particular, the function module may include a power supply module for providing a power voltage.

The circuit board 210 may include a memory slot 211 for receiving and electrically connecting the RAM module 10. The memory slot 211 is also configured for receiving the power voltage from the power supply module and providing the power voltage to the RAM module 10. The memory slot 211 includes a plurality of connection terminals. One of the connection terminals is configured as a power terminal 213 for providing the power voltage.

The RAM module 10 may be plugged in the memory slot 211, with pins of the RAM module 10 being electrically connected to connection terminals of the memory slot 211 respectively. The connection between the pins and the connection terminal enables the RAM module 10 to exchange data with other function modules. For example, data from other function modules can be written and be stored into the RAM module 10, and data stored in the RAM module 10 can be accessed and read out by other function modules such as the CPU. In one embodiment, one of the pins of the RAM module 10 is configured as a power pin 101, the power pin 101 is electrically connected to the power terminal 213 of the memory slot 211, and the power voltage received by the power terminal 213 can be provided to the RAM module 10 through the power pin 101.

The RAM module 10 may have a configuration as illustrated in FIG. 1, for example, the RAM module 10 includes a plurality of memory units and a driving voltage adaptor for converting the power voltage into a driving voltage with a desired value for driving the memory units. Details of the RAM module 10 can be referred to the embodiment as described above.

Because the computing apparatus 30 adopts the RAM module having the driving voltage adaptor, the memory units of the RAM module can avoid enduring excessive driving voltage, and consequently a reliability of the RAM module 10 can be improved and a lifetime of the RAM module 10 can be ensured.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A random access memory (RAM) module, comprising:
a power input terminal that receives a power voltage;
a plurality of memory units for data storage; and
a driving voltage adaptor electrically connected between the power input terminal and the memory units, the driving voltage adaptor configured for receiving the power voltage from the power input terminal, converting the power voltage into a driving voltage having a predetermined value, and outputting the driving voltage to the memory units.

2. The RAM module of claim 1, wherein all of the memory units are a same type of RAM units requiring a same driving voltage.

3. The RAM module of claim 2, wherein each of the memory units is selected from the group consisting of a DDR3 SDRAM unit, a DDR3L SDRAM unit, a DDR3U SDRAM unit, a DDR2 SDRAM unit, and a DDR SDRAM unit.

4. The RAM module of claim 1, wherein the memory units are installed in a print circuit board, and the driving voltage adaptor is an integrated circuit (IC) and is also located on the printed circuit board.

5. The RAM module of claim 4, wherein the driving voltage adaptor is a voltage conversion circuit.

6. The RAM module of claim 5, wherein the driving voltage adaptor is a digital direct current to direct current (DC/DC) converter chip.

7. The RAM module of claim 6, wherein the driving voltage adaptor is a boost circuit that converts the power voltage into a greater driving voltage.

8. The RAM module of claim 6, wherein the driving voltage adaptor is a buck circuit that converts the power voltage into a lower driving voltage.

9. The RAM module of claim 1, wherein the memory units and the driving voltage adaptor are integrated into a one-piece component.

10. A computing apparatus, comprising:
a motherboard comprising a memory slot;
a random access memory (RAM) device plugged in the memory slot, the RAM module comprising:
a plurality of memory units for data storage; and
a driving voltage adaptor electrically connected to the memory units, the voltage conversion being configured for receiving a power voltage from a power terminal of the memory slot, converting the power voltage into a driving voltage having a predetermined value, and outputting the driving voltage to the memory units.

11. The computing apparatus of claim 10, wherein all of the memory units are a same type of RAM units requiring a same driving voltage.

12. The computing apparatus of claim 11, wherein each of the memory units is selected from a group consisting of a DDR3 SDRAM unit, a DDR3L SDRAM unit, a DDR3U SDRAM unit, a DDR2 SDRAM unit, and a DDR SDRAM unit.

13. The computing apparatus of claim 10, wherein the memory units are located on a print circuit board, and the driving voltage adaptor is a form of an integrated circuit (IC) and is also installed at the printed circuit board.

14. The computing apparatus of claim 13, wherein the driving voltage adaptor is a voltage conversion circuit.

15. The computing apparatus of claim 14, wherein the driving voltage adaptor is a digital direct current to direct current (DC/DC) converter chip.

16. The computing apparatus of claim 15, wherein the driving voltage adaptor is a boost circuit that converts the power voltage into a greater driving voltage.

17. The computing apparatus of claim 15, wherein the driving voltage adaptor is a buck circuit that converts the power voltage into a lower driving voltage.

18. The computing apparatus of claim 10, wherein the memory units and the driving voltage adaptor are integrated into a one-piece component.
